(19) United States
(12) Patent Application Publication
(10) Pub. No.: US 2026/0121135 A1
(43) Pub. Date: Apr. 30, 2026

(54) DIRECT CONNECT LOW VOLTAGE BATTERY TO ZONAL CONTROLLER

(71) Applicant: Rivian IP Holdings, LLC, Irvine, CA (US)

(72) Inventors: Sanjeewa Keven SUGATAPALA, Long Beach, CA (US); Chintan SHARMA, Irvine, CA (US); Ashish RAGHUKULA, Lake Forest, CA (US); Kyle LOBO, Westchester, CA (US); Alfredo NECOECHEA HASFIELD, Irvine, CA (US)

(21) Appl. No.: 19/218,038

(22) Filed: May 23, 2025

Related U.S. Application Data
(60) Provisional application No. 63/712,998, filed on Oct. 28, 2024.

(51) Int. Cl. H01M 10/42; G01R 31/388; G01R 31/392; H01M 10/48

(52) U.S. Cl. CPC H01M 10/425; G01R 31/388; G01R 31/392; H01M 10/486; H01M 2010/4271; H01M 2220/20

(57) ABSTRACT

A system and method for directly connecting a low voltage battery to a zonal controller in an electric vehicle. The zonal controller has inputs for directly receiving the positive and negative battery terminals and performs battery management functions including voltage and current sensing. The direct connection may reduce the use of separate sensors and fuses, enabling a compact and simplified battery connection. Packaging the battery and controller in proximity, such as under a vehicle seat, may allow for short, efficient connections.

### CROSS-REFERENCE TO RELATED APPLICATIONS

The present application claims the benefit of U.S. Provisional Application No. 63/712,998, entitled “DIRECT CONNECT LOW VOLTAGE BATTERY TO ZONAL CONTROLLER”, filed Oct. 28, 2024, the entirety of which is incorporated herein for reference

### INTRODUCTION

This application is directed to power and feature management systems for electric vehicles, such as zonal integrated energy storage and distribution architecture that allows for direct connections of the low voltage battery to a zonal controller.

### SUMMARY

The disclosed subject matter provides for zonal architecture for power distribution and other designs thereof that may allow for redundancy in power distribution and feature functionality, while efficiently integrating key power management components in a centralized location. The zonal architecture allows for direct connections of the low voltage battery to a zonal controller.

### BRIEF DESCRIPTION OF THE DRAWINGS

Certain features of the subject technology are set forth in the appended claims. However, for purpose of explanation, several embodiments of the subject technology are set forth in the following figures.

FIG. 1A illustrates an example overhead view of a vehicle with zonal power distribution as described herein.

FIG. 1B illustrates an example side view of a vehicle with zonal power distribution as described herein.

FIG. 2A illustrate an example block diagram that may include a plurality of electronic control units (ECUs).

FIG. 2B illustrates an example block diagram that may include a plurality of ECUs.

FIG. 3A illustrates an example perspective cross-sectional view of a rear seat assembly and power management compartment component.

FIG. 3B illustrates an example perspective cross-sectional top-down view of a rear assembly and power management compartment component.

FIG. 3C illustrates an example top-down view of the rear assembly and associated power management compartment component.

FIG. 4 illustrates an example configuration of direct connection of LV battery to an ECU.

FIG. 5 illustrates an example method of the disclosed subject matter.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

Conventional electric vehicle power systems often use distributed components, leading to increased complexity, wiring, and reduced reliability. There is a need for more integrated and centralized architectures to improve efficiency, reduce costs, enhance safety, or provide functional redundancy. Systems often struggle with optimal power distribution, safety during charging, and efficient packaging of components. The disclosed subject matter may address these challenges through a comprehensive, integrated approach.

The disclosed subject matter provides an integrated power management system for electric vehicles centered around a power management compartment configuration (e.g., centralized power management). The power management compartment integrates key power management components in a centralized location, typically under the rear seat or in the trunk area of the vehicle. This may allow for simplified wiring, reduced connection points, and more efficient use of space compared to conventional distributed architectures.

The disclosed subject matter provides a system or method for directly connecting a low voltage battery to a zonal controller in an electric vehicle. The zonal controller may function as a battery management system for the low voltage battery, directly sensing voltage and current without the need for separate sensors or fuses. This direct connection may minimize package size, reduce the use of traditional components, or enhance reliability. The disclosed subject matter may enable improved packaging, simplified assembly, more accurate battery monitoring, cost savings, or weight savings.

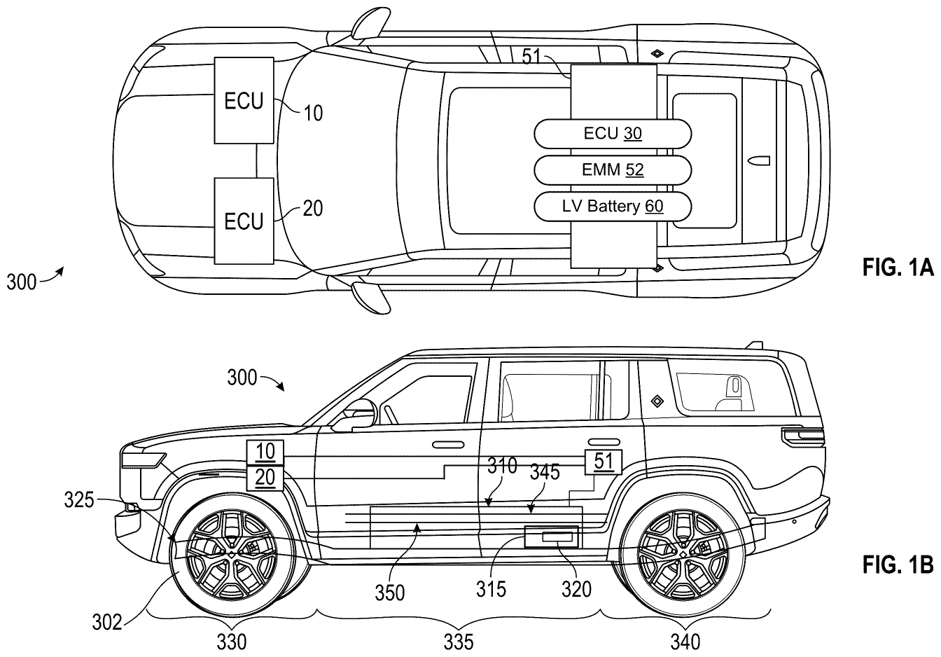

FIG. 1A illustrates an example overhead view of vehicle 300. As further described herein, vehicle 300 may include electronic control units (ECUs) in front portion 330 of vehicle 300 (e.g., ECU 10 and ECU 20), an ECU in rear portion 340 of vehicle 300 (e.g., ECU 30), power management compartment 51 (which may also be referred to as a treehouse), or low voltage (LV) battery 60 (e.g., 9V-16V battery), among other things. As further described herein, ECU 10 may operate components on a first side of a longitudinal axis of vehicle 300, while the ECU 20 may operate components on a second side of the longitudinal axis. The longitudinal axis may be defined as an imaginary line running from the front of vehicle 300 to the rear along its center, dividing vehicle 300 into the first (e.g., left) and second (e.g., right) sides. ECU 30 may operate components at the rear of vehicle 300. ECU 30 may be located within power management compartment 51.

Power management compartment 51 may include ECU 30, energy management module (EMM) 52, or LV battery 60 (e.g., 9V to 16V), among other components. Power management compartment 51 may be a structure that includes power management related components located in a rear of vehicle 300, such as under the second row seat or trunk of vehicle 300. Power management compartment 51 may be the volume of a traditional gas tank and package multiple components as disclosed herein. Power management compartment 51 components may include ECU 30 with left and right MCUs (e.g., MCU 65 or MCU 66), a DC-DC converter (e.g., DC-DC 50), LV battery 60, or an isolation switch (ISOSW) (e.g., fault isolation system 11), among other things. DCDC 50 may be located within EMM 52. ECU 30 may integrate battery management system (BMS) and zonal control functions, managing power distribution between the DC-DC bus and battery bus. Power management compartment 51 may connect with ECU 10 and ECU 20, forming the backbone of the power architecture of vehicle 300. This design may reduce high current feeds from 7 or more in other architectures to just 3, for example, in the disclosed architecture, while eliminating the need for diode ORing, among other things. Power management compartment 51 architecture may provide end-to-end functional redundancy and may enable simplified LV battery management through a single battery feed. This approach may allow for more efficient packaging and reduced system complexity.

FIG. 1B illustrates an example side view of vehicle 300. As shown, the vehicle 300 may include one or more battery packs, such as high voltage (HV) battery pack 310 (e.g., 450V), which may be located near the center body portion 335 of vehicle 300. HV battery pack 310 may be coupled with one or more electrical systems of the vehicle 300 to provide power to the electrical systems. As further described herein, ECU 10 (also may be referred to herein as cast zone controller-EZC 10), ECU 20 (also may be referred to herein as west zone controller-WZC 20), or ECU 30 (also may be referred to herein as south zone controller-SZC 30) may be communicatively connected with or have power distributed with each other and may be functionally redundant for power or other operations of electronic components of vehicle 300.

In one or more implementations, vehicle 300 may be an electric vehicle having one or more electric motors that drive wheels 302 of the vehicle 300 using electric power from HV battery pack 310. In one or more implementations, vehicle 300 may also, or alternatively, include one or more chemically-powered engines, such as a gas-powered engine or a fuel cell powered motor. For example, electric vehicles can be fully electric or partially electric (e.g., hybrid or plug-in hybrid). In various implementations, vehicle 300 may be a fully autonomous vehicle that can navigate roadways without a human operator or driver, a partially autonomous vehicle that can navigate some roadways without a human operator or driver or that can navigate roadways with the supervision of a human operator, may be an unmanned vehicle that can navigate roadways or other pathways without any human occupants, or may be a human operated (non-autonomous) vehicle configured for a human operator.

In the example of FIG. 1B, the vehicle 300 may be implemented as a truck (e.g., a pickup truck) having a battery pack 310. As shown, HV battery pack 310 may include one or more battery modules 315, which may include one or more battery cells 320. However, this is merely illustrative and, in other implementations, HV battery pack 310 may be provided without any battery modules 315 (e.g., in a cell-to-pack configuration).

As shown in FIG. 1B, vehicle 300 may include a support structure such as a chassis 325 (e.g., a frame, internal frame, or other support structure). The chassis 325 may support various components of the vehicle 300. As shown, the chassis 325 may span a front portion 330 (e.g., a hood or bonnet portion), center body portion 335, and a rear portion 340 (e.g., a trunk, payload, or boot portion) of the vehicle 300 in some implementations. In one or more implementations, HV battery pack 310 may be installed on the chassis 325 (e.g., within one or more of the front portions 330, center body portion 335, or the rear portion 340). As shown, HV battery pack 310 may include or be electrically coupled with one or more one busbars (e.g., one or more current collector elements). In the example of FIG. 1B, vehicle 300 includes a first busbar 345 and a second busbar 350, either or both of which may include electrically conductive material to connect or otherwise electrically couple battery module(s) 315 or the battery cell(s) 320 with other electrical components of vehicle 300 to provide electrical power to various systems or components of vehicle 300.

In other implementations, vehicle 300 may be implemented as another type of electric truck, an electric delivery van, an electric automobile, an electric car, an electric motorcycle, an electric scooter, an electric passenger vehicle, an electric passenger or commercial truck, a hybrid vehicle, or other vehicles such as sea or air transport vehicles, planes, helicopters, submarines, boats, or drones, or any other movable apparatus having a battery pack 310 (e.g., that powers the propulsion or drive components of the moveable apparatus).

The disclosed multi-zonal architecture may allow for reduced wiring when compared to other architectures. Shorter wires may provide for less mass and therefore vehicle 300 may weigh less. While wire length generally may not significantly affect cost for small gauge wires, it may influence the overall mass and flexibility of the harness. Longer wires may increase harness bulk, potentially complicating installation due to reduced flexibility.

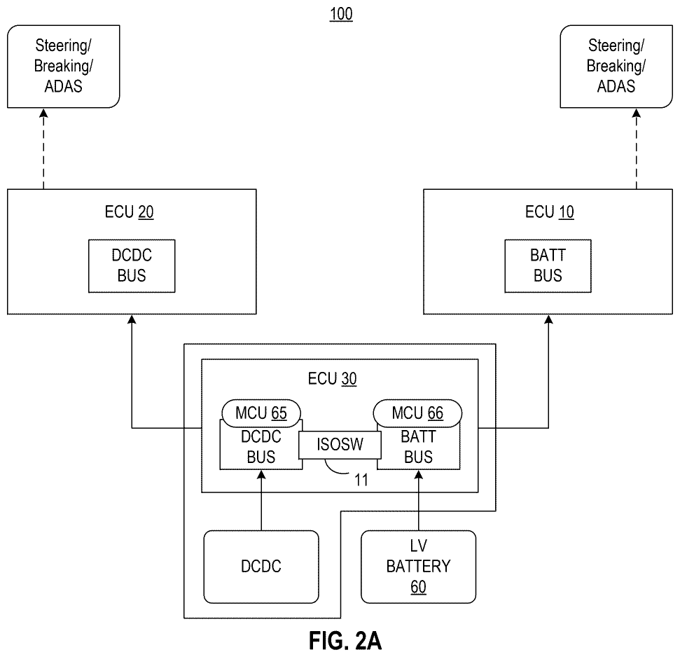

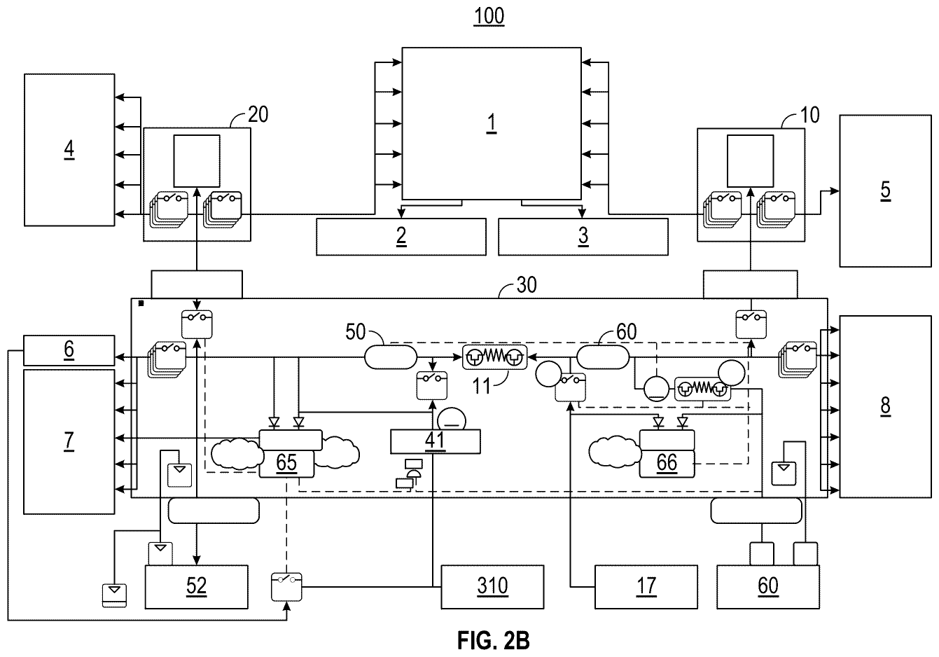

FIG. 2A and FIG. 2B illustrate exemplary block diagrams of system 100 that may include a plurality of ECUs of vehicle 300. An ECU is an embedded system that may control one or more of the electrical systems or subsystems in a vehicle, such as steering, breaking, advanced driver assistance system (ADAS), or the like. The positioning and connections of ECU 10, ECU 20, or ECU 30 may provide for a level of redundancy for faults, which may be caused by collisions or other malfunctions. The design of system 100 may allow vehicle 300 to safely operate for a period after the fault, such as being able to drive vehicle 300 (e.g., steer, brake, or accelerate) to a safe position off of a roadway or being able to operate electronic controlled functions (e.g., door latches) of vehicle 300, among other things. As shown, ECU 10, ECU 20, or ECU 30 may be connected with DCDC 50 (also referred herein as DCDC bus 50 or DCDC converter 50) to operate DCDC loads and a low voltage (LV) battery 60 (e.g., 12V battery or LV battery bus 60) to operate LV battery loads.

There may be different types of operations such as post-crash operation, sleep operation, jumpstart operation, manufacturing power operation, DCDC fault operation, LV battery fault operation, or normal operation associated with driving, among others. FIG. 2B illustrates an exemplary block diagram of system 100 in normal operation associated with driving. In an example, one or more ECUs (e.g., ECU 30) may include a fault isolation system 11. Fault isolation system 11 may include an isolation switch. In some configurations, in consideration of safety, only one ECU (e.g., ECU 30) may include fault isolation system 11. There may be a common bus that allows for bidirectional power to be transmitted to and from LV battery 60 that may be a function of using fault isolation system 11. In the event of a failure of the DCDC 50 (within EMM 52) or LV battery 60, the common bus will retain operation (e.g., will be available).

With continued reference to FIG. 2B, each ECU may have on or more dedicated functions that may be powered by DCDC 50, LV battery 60, or LV DCDC 41. ECU 10 may operate or connect with (e.g., communication or power) functions 1, functions 2, functions 3, and functions 5. Functions 1 may include functions such as first row universal serial bus, or electronic stability program (ESP), among other things. Functions 2 may include functions such as right door latch, passenger seat motor, right headlamp, alarm module, or frunk latch, among other things. In this example, functions 1, functions 2, functions 3, or functions 5 of ECU 10 may be powered by DCDC 50 (which may be the primary power) or LV battery 60 (which may be the secondary power). ECU 10 may be located on the right front of vehicle 300 and therefore may operate functions primarily for the right portion of vehicle 300.

As shown in FIG. 2B, ECU 20 may operate functions 1, functions 2, functions 3, or functions 4. Functions 1 may include functions such as front suspension valves, or autonomy control module, among other things. Functions 4 may include functions such as steering angle sensor, front wiper motor, left door latches, left headlamp, exterior near field communication (NFC), or on-board diagnostics (OBD) port, among other things. Functions 1 or functions 2 may include functions such as electric power assisted steering (EPAS), charge port door, interior NFC, or electric powered assisted breaking, among other things. In this example, functions 1, functions 2, functions 3, or functions 4 of ECU 20 may be powered by DCDC 50 (which may be the primary power) or LV battery 60 (which may be the secondary power). ECU 20 may be located on the left front of vehicle 300 and therefore may operate functions primarily for the left portion of vehicle 300.

As shown in FIG. 2B, ECU 30 may operate functions 6, functions 7, functions 8, and jumpstart functions. ECU 30 may be connected with jumpstart access 17. Jumpstart access 17 may allow an external power source (e.g., jumpstart pack) to connect with ECU 30 in order to jumpstart electronic functions of vehicle 300, such as when LV battery 60 is depleted. As further described herein, jumpstart access 17 may have multiple routes. Functions 6 may include functions such as main contactor or DCFC contactor. Functions 7 or functions 8 may include functions such as rear vehicle access system sensors, liftgate latch, trailer brake, right lamp rear, left lamp rear, right trailer brake lamp, rear suspension valves, DCDC logic power, BMS voltage/isolation monitoring, park lock, HV pack shunt monitor, radio farm, chargeport PC/IO, rear radar, or ethernet components, among other things. In this example, functions 6, functions 7, or functions 8 of ECU 30 may be powered by DCDC 50 (which may be the primary power) or LV battery 60 (which may be the secondary power). ECU 30 may be located on the rear of vehicle 300 (e.g., under a rear seat) and therefore may operate functions primarily for the rear portion of vehicle 300.

System 100 may include a battery management system (BMS). The BMS may be located at or near HV battery pack 310, which LV DCDC 41 converts the HV DC to a lower voltage, such as 14V. LV DCDC 41 may help reduce the need for LV battery 60 for some operations, such as when vehicle 300 is in standby mode (e.g., parked). It is contemplated that the functions disclosed herein (e.g., functions 1 through functions 8) may be controlled by other ECUs or powered by any of the listed power sources.

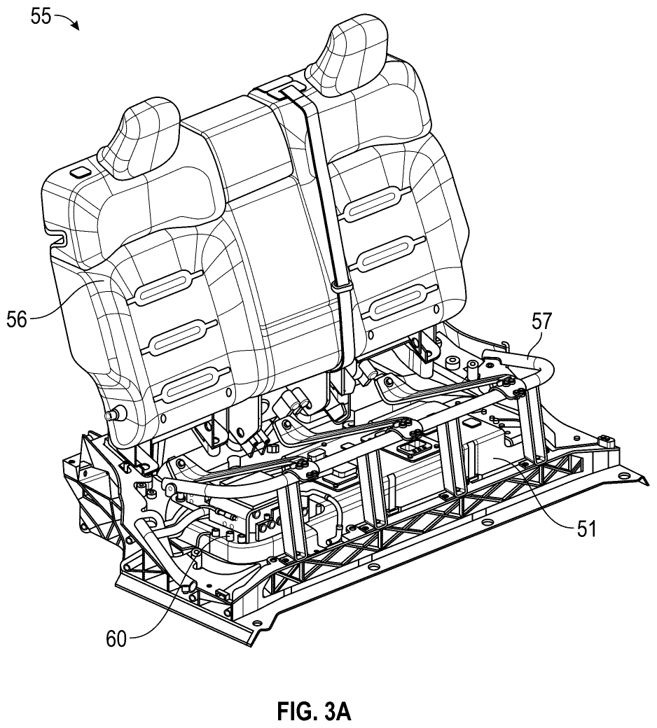

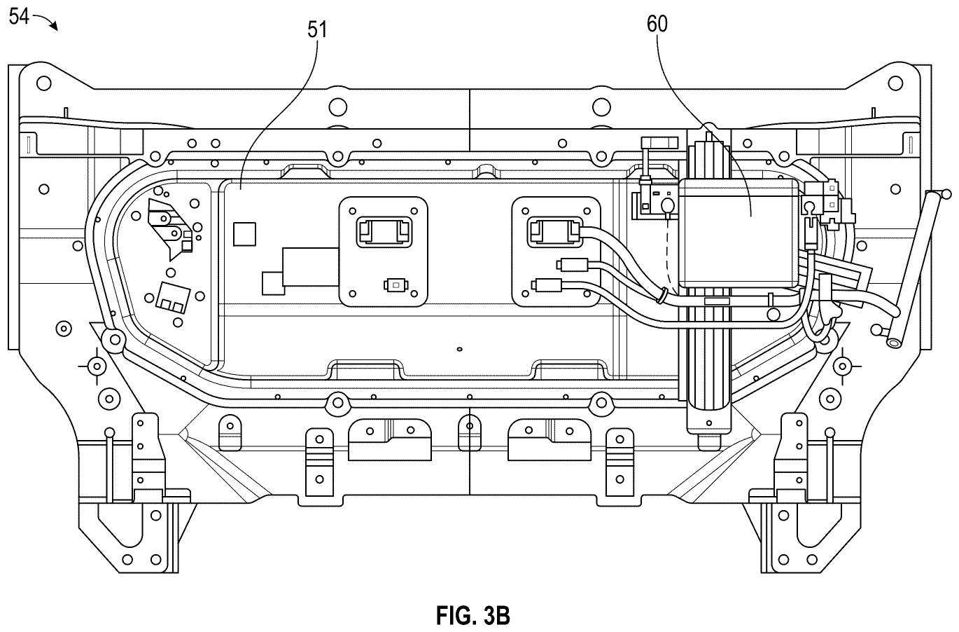

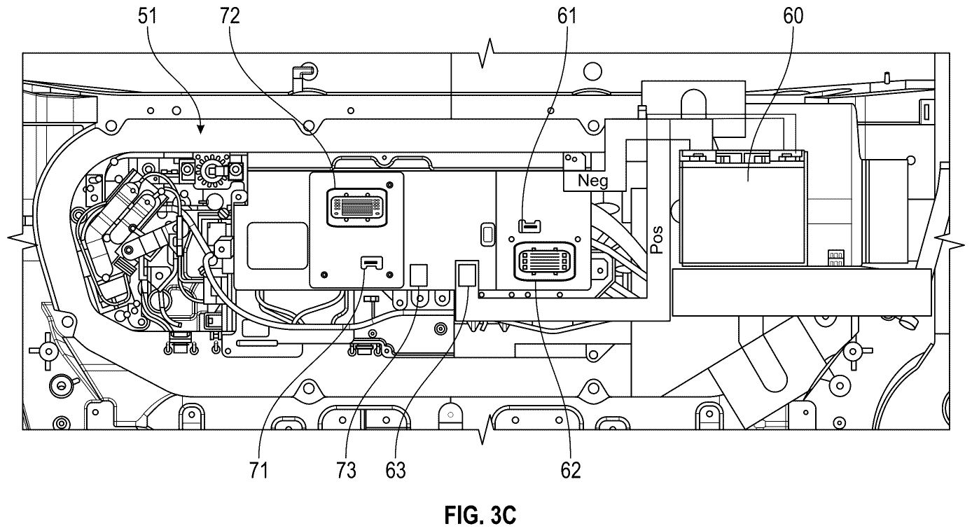

FIG. 3A illustrates an exemplary perspective cross-sectional view of a rear seat assembly 55 of vehicle 300 and the power management compartment 51 component. Power management compartment 51 may be located under the rear seat assembly 55 of vehicle 300, such as under one or more seats 56.

Power management compartment 51 may be rectangular or other shaped structure that houses electrical components such as ECU 30, DC-DC 50, or other sophisticated power management systems. Power management compartment 51, as shown, may be flanked by structural components 57 of rear seat assembly 55 for protecting power management compartment 51 or support seating elements, such as cushions. Structural components 57 may serve as mounting brackets and structural supports so that power management compartment 51 remains secure during vehicle operation.

LV battery 60 may abut or may be otherwise proximate to power management compartment 51 and may be angled in a position that maximizes space utilization, minimizes the likelihood of altering a passengers seating comfort, and maintain accessibility for maintenance. The assembly may be mounted on the floor pan of vehicle 300.

The packaging assembly associated with power management compartment 51 illustrates the integration of critical systems beneath passenger areas, optimizing space usage while ensuring easy access for maintenance and upgrades.

FIG. 3B illustrates an exemplary top-down view of the rear assembly 54 which include power management compartment 51 integrated into the floor structure of vehicle 300. In this alternative example, LV battery 60 may be connected to chassis ground via the negative terminal and directly to the ECU 30 (e.g., SZC) at the positive terminal.

FIG. 3C illustrates an exemplary configuration of power management compartment 51. As shown, connectors may be positioned in a certain manner to help accommodate routing of wires and connections to components. In addition, LV battery 60 is directly connected with ECU 30 (housed within power management compartment 51) with negative terminal 78 and positive terminal 77. There may be a temperature sensor 79 connected with LV battery 60. ECU 30 may interface with one or more temperature sensors 79 mounted on LV battery to monitor thermal conditions. In this example, body RH connector 62 is placed in the shown position near the rear plane of LV battery 60. This positioning may assist with the routing of wiring and reduce the bending needed to maneuver around LV battery 60. FIG. 3C further illustrates example positioning of EZC power connector 61 (e.g., connects with ECU 10), LV battery input connector 63 (e.g., connects positive terminal of LV battery 60), body LH connector 72, WZC power connector 71 (e.g., connects with ECU 20), or DCDC connector 73 (e.g., connects with DCDC 50).

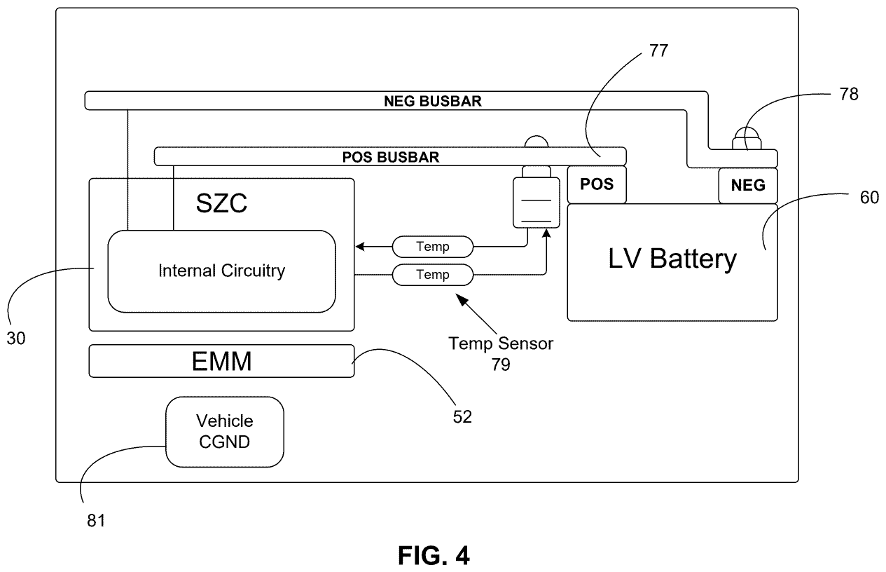

FIG. 4 illustrates an example configuration of direct connection of LV battery 60 to an ECU 30. LV battery 60 may be directly connected to the ECU 30 via positive terminal 77 (e.g., positive busbar) and negative terminal 78 (e.g., negative busbar). This direct connection may be made using semi-flexible busbars, which provide a low-resistance electrical path while allowing for some movement to accommodate vibration and potential deformation in a crash scenario. These busbars may be designed with low electrical resistance to minimize power losses and voltage drop. The busbars may be durable enough to withstand the environmental conditions present in a vehicle, including temperature extremes and potential exposure to fluids. The busbar design may be compact to contribute to the overall space efficiency of the system. Furthermore, the busbar design may minimize electromagnetic emissions and susceptibility to interference. The semi-flexible busbar may be designed to integrate temperature sensor components, which may reduce wiring or other components. The “semi-flexible” characteristic may be particularly valuable in vehicle environments in which components may shift slightly during operation due to vibration, thermal expansion, or chassis flex, helping to prevent connection fatigue while maintaining reliable electrical conductivity between the battery terminals and the zonal controller.

By measuring current flow through the negative terminal input 78, ECU 30 may track battery charge and discharge rates or other battery performance metrics to estimate its overall health and capacity degradation. Using voltage, current, or temperature data, ECU 30 can accurately estimate the state of charge of LV battery 60. ECU 30 may be connected with vehicle common ground (CGND) 81. The disclosed configuration may help reduce the need for separate voltage sense lines, fuses, or ground studs. With the ability to directly monitor and control current flow, external fuses between LV battery 60 and ECU 10 can potentially be eliminated, further simplifying the system. This direct connection strategy may improve accuracy in voltage and current monitoring while reducing parts count and simplifying assembly. There may be examples in which LV battery 60, DC-DC converter 50, or central ECU 30 may share common ground 81 within power management compartment 51. ECU 30 may manage charging of LV battery 60 from the high voltage system (typically via a DC-DC converter 50) and control discharge to various vehicle systems.

This unified grounding approach may improve electromagnetic compatibility (EMC) and may allow for more accurate voltage sensing and current monitoring. ECU 30 may incorporate battery monitoring functions previously handled by separate sensors. This integration may eliminate the need for dedicated battery monitoring hardware, reducing system complexity, or cost. ECU 30 may directly measure battery voltage, current, or temperature, providing more accurate and reliable health monitoring associated with the state of the low voltage battery. The one or more temperature sensors may be mounted on the battery to monitor thermal conditions.

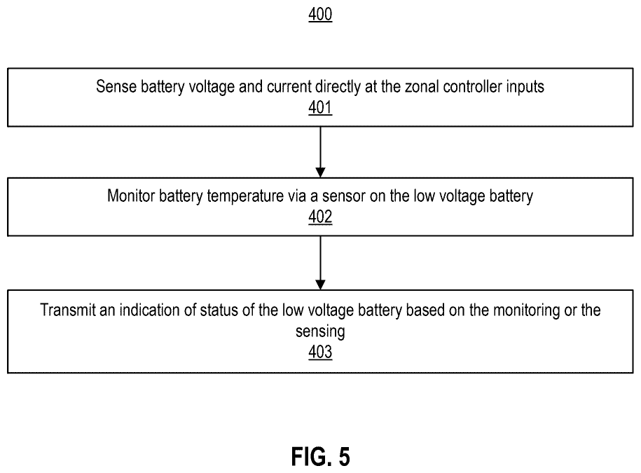

FIG. 5 illustrates an example method 400 for connecting a low voltage battery in an electric vehicle as disclosed herein. At step 401, voltage and current associated with LV battery 60 may be sensed directly at the zonal controller inputs (e.g., ECU 30 inputs). By integrating the sensing capabilities directly into the zonal controller, the system can achieve improved accuracy and reduced complexity. In this context, ECU 30 takes on the additional role of battery management, leveraging its strategic position and advanced processing capabilities.

At step 402, battery temperature may be monitored via a sensor on LV battery 60. Temperature monitoring may help maintain optimal battery performance and longevity. The sensor, such as a thermistor or similar temperature-sensitive device, may be placed directly on LV battery 60 to ensure accurate readings. This placement may allow for real-time temperature data, which may be helpful for preventing overheating and managing charging cycles effectively. The direct attachment of the sensor to LV battery 60 may also minimize potential interference or lag in temperature readings that might occur with less proximate sensor placements.

At step 403, an indication of status of the low voltage battery may be transmitted based on the monitoring or the sensing. This status indication may serve multiple purposes within the vehicle's electrical ecosystem. It can inform the main control systems of vehicle 300 about the battery's health, charge level, and overall performance. This information may be used for various vehicle functions, including power management, fault diagnosis associated with a power source such as LV battery 60, or driver notifications. The transmission may occur over the vehicle's internal communication network, possibly using protocols like CAN (Controller Arca Network) or Ethernet.

It is also contemplated herein that the low voltage battery and zonal controller may be packaged in proximity under a seat of the electric vehicle. This packaging strategy helps maximize space utilization and offers protection for these components. It allows for shorter cable runs, potentially reducing electrical resistance and improving system efficiency.

The methods described herein, combining direct sensing, integrated temperature monitoring, and strategic packaging, represents an approach to low voltage battery management in electric vehicles. The capabilities of the disclosed zonal controllers may be leveraged to create a more efficient, compact, or intelligent power management system. This approach may optimize space and may improve electrical performance while also allowing for more advanced battery management strategies in electric vehicle designs.

The rear centralized zonal architecture associated with power management compartment 51 may provide enhanced crash safety by shielding critical components from front, rear, or side impacts. Power management compartment 51 may be in an area reinforced with strong structural components to absorb and dissipate impact energy which may be associated with a crash, minimizing injury to occupants (and secondarily power management compartment 51). This centralized and protected location of components reduces the likelihood of damage to multiple systems simultaneously in severe crash scenarios, potentially improving occupant safety and post-crash response capabilities.

The methods, systems, or apparatuses disclosed herein may be incorporated into electric vehicles or other devices. The circuit blocks disclosed herein may be distributed with or combined with one or more ECUs or other devices. The methods, systems, or apparatuses disclosed herein may be incorporated into products, such as various feature specific or zone specific electronic control units (ECUs). The information (e.g., voltage, current, resistance, or proposed functionality), as disclosed herein in the figures and text, is provided for illustrative purposes and other scenarios are contemplated herein.

Systems, methods, devices, or non-transitory computer-readable media with regard to connecting a low voltage battery in a vehicle are disclosed herein. A system may provide for a low voltage battery having positive and negative terminals; and an ECU having inputs for directly receiving the positive and negative battery terminals, wherein the ECU directly senses battery voltage. There may be a first connection, wherein the first connection connects the positive terminal of the low voltage battery to the ECU; and a second connection, wherein the second connection connects the negative terminal of the low voltage battery to the ECU. The ECU may be a zonal controller or comprise an energy management module. The ECU may monitor battery temperature via a temperature sensor on the battery. The ECU may provide a shared grounding point for the battery negative terminal and other vehicle electronics. The ECU and the low voltage battery may be packaged in proximity under a seat of the vehicle. The ECU may perform battery management functions including state of charge estimation, state of health monitoring, or fault detection. The system may further include semi-flexible busbars connecting the positive and negative terminals of the low voltage battery to the inputs of the ECU. The vehicle may be an electric vehicle or a hybrid-electric vehicle. The low voltage battery may power components in two or more electronic control units. The low voltage battery may be approximately 12 volts. The ECU may directly sense battery current. All combinations (including the removal or addition of steps) in this paragraph and the above paragraphs are contemplated in a manner that is consistent with the other portions of the detailed description.

A method may include monitoring battery voltage and current directly at the ECU inputs; monitoring battery temperature via a sensor on the low voltage battery; and transmitting an indication of status of the low voltage battery based on the monitoring. The method may further comprise packaging the low voltage battery and ECU in proximity under a seat of the electric vehicle. Another method may include directly connecting positive and negative terminals of a low voltage battery to inputs of a ECU, wherein the ECU performs battery management functions; monitoring battery voltage and current directly at the ECU inputs; and monitoring battery temperature via a sensor on the low voltage battery. All combinations (including the removal or addition of steps) in this paragraph and the above paragraphs are contemplated in a manner that is consistent with the other portions of the detailed description.

A device may include one or more processors configured to: monitor battery voltage and current directly at the ECU inputs; monitor battery temperature via a sensor on the low voltage battery; and transmit an indication of status of the low voltage battery based on the monitoring. Another device may include one or more processors configured to: directly connect positive and negative terminals of a low voltage battery to inputs of a ECU, wherein the ECU performs battery management functions; sense battery voltage and current directly at the ECU inputs; and monitor battery temperature via a sensor on the low voltage battery. All combinations (including the removal or addition of steps) in this paragraph and the above paragraphs are contemplated in a manner that is consistent with the other portions of the detailed description.

A non-transitory computer-readable medium may store a set of instructions for connecting a low voltage battery in an electric vehicle, the set of instructions comprising: one or more instructions that, when executed by one or more processors of a device, cause the device to: monitor battery voltage and current directly at the ECU inputs; monitor battery temperature via a sensor on the low voltage battery; and transmit an indication of status of the low voltage battery based on the monitoring or the sensing. Another non-transitory computer-readable medium may store a set of instructions for connecting a low voltage battery in an electric vehicle, the set of instructions comprising: one or more instructions that, when executed by one or more processors of a device, cause the device to: directly connect positive and negative terminals of a low voltage battery to inputs of a ECU, wherein the ECU performs battery management functions; sense battery voltage and current directly at the ECU inputs; and monitor battery temperature via a sensor on the low voltage battery. The low voltage battery may be approximately 12 volts (V). The ECU may directly monitor battery current. All combinations (including the removal or addition of steps) in this paragraph and the above paragraphs are contemplated in a manner that is consistent with the other portions of the detailed description.

The term “or” is used inclusively unless otherwise disclosed. As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A system for low voltage battery management in a vehicle, comprising:
a low voltage battery having a positive terminal and a negative terminal;
an electronic control unit (ECU) having inputs for directly receiving the positive terminal and negative battery terminal, wherein the ECU directly senses battery voltage;
a first connection, wherein the first connection connects the positive terminal of the low voltage battery to the ECU; and
a second connection, wherein the second connection connects the negative terminal of the low voltage battery to the ECU.

2. The system of claim 1, wherein the ECU is within a power management compartment.

3. The system of claim 2, wherein the power management compartment comprises an energy management module.

4. The system of claim 1, wherein the ECU monitors battery temperature via a temperature sensor on the battery.

5. The system of claim 1, wherein the ECU provides a shared grounding point for the negative battery terminal and other vehicle electronics.

6. The system of claim 1, wherein the ECU and the low voltage battery are packaged in proximity under a seat of the vehicle.

7. The system of claim 1, wherein the ECU performs battery management functions, wherein the battery management functions comprise state of charge estimation.

8. The system of claim 1, wherein:
the first connection comprises a first semi-flexible busbar, and
the second connection comprises a second semi-flexible busbar, wherein the first semi-flexible busbar or the second semi-flexible busbar comprises a temperature sensor.

9. The system of claim 1, wherein the vehicle is an electric vehicle or hybrid-electric vehicle.

10. The system of claim 7, wherein the battery management functions comprise health monitoring associated with a state of the low voltage battery or detecting a fault associated with the low voltage battery.

11. The system of claim 1, wherein the low voltage battery powers components in two or more electronic control units.

12. The system of claim 1, wherein the low voltage battery is approximately 12 volts.

13. The system of claim 1, wherein the ECU directly senses battery current through the negative terminal.

14. An electric vehicle comprising:
a low voltage battery, wherein the low voltage battery comprises a positive terminal and a negative terminal; and
a power management compartment, wherein the power management compartment comprises:
an energy management module (EMM); and
an electronic control unit (ECU), wherein the ECU comprises:
a first connection to the positive terminal of the low voltage battery, and
a second connection to the negative terminal of the low voltage battery.

15. The electric vehicle of claim 14, wherein:
the first connection comprises a first semi-flexible busbar,
the second connection comprises a second semi-flexible busbar, wherein the first semi-flexible busbar or the second semi-flexible busbar comprises a temperature sensor.

16. The electric vehicle of claim 14, wherein the ECU determines a state of charge of the low voltage battery based on information associated with the first connection or second connection.

17. The electric vehicle of claim 14, wherein the ECU is connected with a common ground of the electric vehicle.

18. A method for monitoring a low voltage battery in an electric vehicle, comprising:
monitoring, at electronic control unit (ECU) inputs connected with the low voltage battery, voltage associated with the low voltage battery and a current associated with the low voltage battery;
monitoring battery temperature via a sensor associated with the low voltage battery;
determining a status of the low voltage battery based on the voltage, the current, and the temperature, wherein the status comprises the state of charge of the low voltage battery; and
transmitting an indication of the status of the low voltage battery.

19. The method of claim 18, wherein the ECU comprises:
a first connection to a positive terminal of the low voltage battery, and
a second connection to a negative terminal of the low voltage battery.

20. The method of claim 19, wherein:
the first connection comprises a first semi-flexible busbar, or
the second connection comprises a second semi-flexible busbar.
